(19) United States
(12) Patent Application Publication
(10) Pub. No.: US 2025/0380489 A1
(43) Pub. Date: Dec. 11, 2025

(54) SEMICONDUCTOR DEVICE WITH INTEGRATED FIRST AND SECOND TYPE SUB CELLS

(71) Applicant: Huawei Digital Power Technologies Co., Ltd., Shenzhen (CN)

(72) Inventor: Samir Mouhoubi, Nuremberg (DE)

(73) Assignee: Huawei Digital Power Technologies Co., Ltd., Shenzhen (CN)

(21) Appl. No.: 19/260,032

(22) Filed: Jul. 3, 2025

Related U.S. Application Data
(63) Continuation of application No. PCT/EP2023/066594, filed on Jun. 20, 2023.

(51) Int. Cl. H10D 84/00; H10D 8/01; H10D 8/60; H10D 30/01; H10D 30/47; H10D 62/824; H10D 64/23; H10D 84/01

(52) U.S. Cl. CPC H10D 84/101; H10D 8/051; H10D 8/60; H10D 30/015; H10D 30/475; H10D 64/257; H10D 84/0107; H10D 62/824

(57) ABSTRACT

The disclosure relates to a semiconductor device (100), comprising: a die layer (110) comprising a top surface and a bottom surface opposing the top surface; wherein the die layer (110) forms a plurality of unit cells (120) arranged side-by-side across the top surface of the die layer (110), wherein each unit cell (120) comprises a sub cell of a first type (120a) and a sub cell of a second type (120b) which are both integrated in the unit cell (120), wherein the sub cell of the first type (120a) comprises a first electrode (121), a second electrode (122) and a third electrode (123) formed at the top surface of the die layer (110), a first one of the three electrodes (121, 122, 123) being arranged to enclose a second one of the three electrodes (121, 122, 123); and the first one and the second one of the three electrodes (121, 122, 123) being arranged to enclose a third one of the three electrodes (121, 122, 123); wherein the sub cells of the first type (120a) form high electron mobility transistor, HEMT, cells; and wherein the sub cells of the second type (120b) form Schottky Barrier Diode, SBD, cells.

### CROSS-REFERENCE TO RELATED APPLICATIONS

This application is a continuation of International Application No. PCT/EP2023/066594, filed on Jun. 20, 2023, the disclosure of which is hereby incorporated by reference in its entirety.

### TECHNICAL FIELD

The disclosure relates to the field of Semiconductor Technology for power device applications, for example wide bandgap power devices. The disclosure relates to a semiconductor device with a plurality of unit cells, wherein in each unit cell a first type sub cell is integrated with a second type sub cell, the first type sub cell forming a High Electron Mobility Transistor (HEMT) cell and the second type sub cell forming a Schottky Barrier Diode (SBD) cell and a method for manufacturing such semiconductor device. A hexagonal lateral GaN (Gallium Nitride)-eHEMT (enhanced HEMT) with intrinsic monolithically integrated SBD is also disclosed.

### BACKGROUND

Many electronic systems and applications rely on power switching circuits that require power devices to operate in two modes: 1) On-state mode: The power device is in forward mode allowing the conduction of current; 2) Off-state mode: The power device is blocking the conduction of current and sustaining a high voltage. The switching between these two modes, forces the power device to operate for very short times, e.g., at each switching event, in a so-called reverse mode or third quadrant: in this configuration, the polarity of the device is inverted and a reverse current needs to be evacuated. In established technologies (like Silicon), the switching device, for example a power MOSFET, contains inherently a body diode that is used to assist the evacuation of this reverse current.

Gallium Nitride (GaN) is a new emerging technology that exhibits promising potential to replace Silicon in power applications where fast switching and high power is needed. The value of GaN resides in its wide bandgap which is ˜3.4 eV compared to ˜1.1 eV for Silicon. However, many challenges face the deployment of GaN. Regarding reverse mode conduction: GaN HEMT devices suffer from the following weaknesses: They do not contain a body diode like Silicon based devices. The reverse conduction depends on the threshold voltage in reverse conduction (Vrc) value; which depends in its turn on the forward threshold voltage (Vth). It is technologically difficult to tune both of them independently: a compromise is needed. In the current status of the technology, Vth stability is not guaranteed; dynamic Vth shifts can occur. Therefore, it can be challenging to control reverse conduction mode and associated losses accurately.

### SUMMARY

This disclosure provides a solution for overcoming the limitations of the GaN technology with respect to reverse conduction and stability as described above.

In particular, the disclosure provides a solution for solving the weaknesses of the GaN HEMT device related to the reverse conduction.

The foregoing and other objectives are achieved by the features of the independent claims. Further implementation forms are apparent from the dependent claims, the description and the figures.

Embodiments of the disclosure present a solution for improving reverse conduction of the GaN HEMT by monolithically integrating an intrinsic SBD in the unit cell of the GaN HEMT to limit the losses during the switching event.

The disclosure provides a solution for the above-described weakness of the GaN HEMT device/technology in the third quadrant of the Ids/Vds diagram, e.g., during reverse conduction mode. The solution presented hereinafter is a novel implementation that is based on monolithic integration as described below. The solution presented in this disclosure presents an integration based on a closed cell design. Different implementations together with their specific technical advantages are exposed in the following sections.

A main idea of embodiments described in this disclosure is to perform a monolithic integration of the SBD in the pitch of the GaN HEMT unit cell in order to maximize the protection of the power device. A new design is implemented where the power device is formed with unit cells that have a closed shape (and not stripe-like shapes). Inside each HEMT unit cell, an SBD device is inserted.

In this disclosure, a novel semiconductor device, in particular wide bandgap power device such as GaN-HEMT device is presented that provides reduced constraints caused by a small pitch on the metallization, improved area/cost, reduced parasitics and compliance with advanced and efficient packaging schemes.

The novel semiconductor device is based on a unit cell configuration, e.g., of a closed geometrical contour such as for example hexagonal shape, with a full layout and metallization scheme suitable for bond on active packaging.

In this disclosure, semiconductor devices, in particular HEMT devices and GaN-HEMT devices are described. A high-electron-mobility transistor (HEMT) is a field-effect transistor incorporating a junction between two materials with different band gaps, e.g., a heterojunction as the channel instead of a doped region (as is generally the case for a MOSFET). Commonly used material combinations are GaAs, AlGaAs, InGaAs and GaN. GaN HEMTs are particularly suitable due to their high-power performance. They can be used in a wide range of applications, such as power supplies, DC-to-DC converters, motor controllers and many other applications.

The novel semiconductor device introduced in this disclosure can be produced by using a variety of technologies. This can be for example: GaN-on-Si, GaN-on-GaN, GaN-on-SiC, GaN-on-SOI, GaN-on-QST, etc.

The solution presented hereinafter is applicable to any power conversion system or architecture using semiconductor power devices. The solution is applicable when high blocking voltage, high current density and high switching frequency are required. The solution is applicable, as an example, in inductively switching circuits, where there is a need of current freewheeling, e.g., reverse conduction mode, during turn-off of a power semiconductor device. The solution is applicable to all power electronic systems targeting energy loss, application size and total application cost reduction.

The products in which the disclosed solution can be applied are all power electronics products, particularly DC and AC converters used in photovoltaics, electric vehicles, chargers and on-board chargers, data centers, railway, telecom, servers and others.

In order to describe the disclosure in detail, the following terms and notations will be used.
MOS Metal Oxide Semiconductor
FET Field Effect Transistor
MOSFET Metal Oxide Semiconductor Field Effect Transistor
HEMT High Electron Mobility Transistor
SiC Silicon Carbide
GaN Gallium Nitride
JFET Junction Field Effect Transistor
SBD Schottky Barrier Diode
2DEG Two Dimentional Electron Gas
Vth Threshold voltage
Vrc Threshold voltage in Reverse conduction
Ron On-state resistance
HV High Voltage
MV Medium Voltage
WBG Wide BandGap

On-state mode: Electrical state in which the power device is in forward mode (allowing the conduction of current).

Off-state mode: Electrical state in which the power device is blocking the conduction of current and sustaining a high voltage.

Switching event: Lapse of time during which the power device changes its electrical state.

Band gap: Energy domain in which no electronic states exist (energy space between the top of the valence band and the bottom of the conduction band).

Wide bandgap: Bandgap larger than 2 eV.

According to a first aspect, the disclosure relates to a semiconductor device, comprising: a die layer comprising a top surface and a bottom surface opposing the top surface; wherein the die layer forms a plurality of unit cells arranged side-by-side across the top surface of the die layer, wherein each unit cell comprises a sub cell of a first type and a sub cell of a second type which are both integrated in the unit cell, wherein the sub cell of the first type comprises a first electrode, a second electrode and a third electrode formed at the top surface of the die layer, a first one of the three electrodes being arranged to enclose a second one of the three electrodes; and the first one and the second one of the three electrodes being arranged to enclose a third one of the three electrodes; wherein the sub cells of the first type form high electron mobility transistor, HEMT, cells; and wherein the sub cells of the second type form Schottky Barrier Diode, SBD, cells.

In such a semiconductor device the inserted SBD sub cells provide current conduction capability in reverse mode without the need of external Schottky diode. By such monolithically integration of SBD sub cells, additional parasitics can be reduced (compared to solutions where the SBD is externally connected to the HEMT). Integration of SBD cells can replace the functionality of the body diodes in semiconductor technologies that do not contain a body diode, like GaN technology, for example. The absence of the body diode that is used to assist the evacuation of reverse current can be retrieved by such integration of SBD cells.

In an exemplary implementation of the semiconductor device, the semiconductor device comprises a GaN die layer. The GaN die layer allows fast switching and high power due to its wide bandgap which is ˜3.4 eV compared to ˜1.1 eV for Silicon.

In an exemplary implementation of the semiconductor device, each sub cell of the second type comprises a first electrode and a second electrode formed at the top surface of the die layer; wherein the second electrode of the sub cell of the second type is integrally formed within the third electrode of the sub cell of the first type. Accordingly, the unit cells can be space efficiently implemented. Multiple unit cells can be placed side-by-side without waste of die layer.

In an exemplary implementation of the semiconductor device, the second electrode of the sub cell of the second type forms a Cathode of the SBD cell, the Cathode of the SBD cell being integrally formed within a Drain of the HEMT cell. This allows to integrate SBD cells with HEMT cells for inhibiting reverse conduction and improving stability at high power and fast switching capabilities.

In an exemplary implementation of the semiconductor device, each of the second electrode and the first electrode of a sub cell of the first type forms a closed geometrical contour around the third electrode of the sub cell of the first type; wherein the closed geometrical contour of the first electrode or the second electrode or of both the first electrode and the second electrode is broken at one or more points at which the first electrode of the sub cell of the second type is formed. In such semiconductor device, a bond pad configuration inside the active area of the semiconductor device can be used while in conventional devices packaging can only be implemented with a bond pad configuration outside the active area.

In an exemplary implementation of the semiconductor device, the semiconductor device comprises: an insulating layer formed at the one or more points to electrically insulate the first electrode of the sub cell of the second type from the first electrode or from both the first electrode and the second electrode of the sub cell of the first type. This insulation layer can be realized by several ways. The most common one is to destroy the 2DEG (2-dimensional electron gas) by implantation of nitrogen or other chemical elements.

In an exemplary implementation of the semiconductor device, an Anode of the SBD cell is arranged inside a Source or inside a Gate of the HEMT cell, the Anode being insulated by the insulating layer. In this way, the path for the current conduction of the SBD is opened. The insulation layer prevents electrical shorts between the Drain and Source.

In an exemplary implementation of the semiconductor device, each of the second electrode and the first electrode of a sub cell of the first type forms a closed geometrical contour around the third electrode of the sub cell of the first type. In such semiconductor device, a bond pad configuration inside the active area of the semiconductor device can be used while in conventional devices packaging can only be implemented with a bond pad configuration outside the active area.

In an exemplary implementation of the semiconductor device, an Anode of the SBD cell is arranged between a Drain and a Gate of the HEMT cell. In this way, the path for the current conduction of the SBD is opened. This configuration corresponds to FIG. 3 described below.

In an exemplary implementation of the semiconductor device, the closed geometrical contour is symmetrical about one or more directions along the top surface of the die layer; and the closed geometrical contour has at least one sharp corner, at least one rounded corner and/or at least one cut corner or any combination thereof. This provides flexible design and management of eventual electrical field peaks at sharp corners. The contour of the unit cell can be adapted to the available shape of the die layer.

In an exemplary implementation of the semiconductor device, at least one of the first electrode, the second electrode and the third electrode is stretched in a direction along the top surface of the die layer. This provides design flexibility.

In an exemplary implementation of the semiconductor device, the closed geometrical contour is a hexagon, an octagon, a triangle, a square, a rectangular or a circle. In this way, different designs can be implemented.

In an exemplary implementation of the semiconductor device, the die layer comprises a Gallium Nitride, GaN, layer and an Aluminum Gallium Nitride, AlGaN, layer formed on top of the GaN layer; wherein any of the electrodes of the SBD cell) and the electrodes of the HEMT cell forms a field plate above the AlGaN layer. The field plate allows to shape the electric field at the surface between AlGaN and above layers for protection of Schottky edges and Cathode edges. This improves stability of the semiconductor device.

In an exemplary implementation of the semiconductor device, the first electrode of the sub cell corresponding to the Anode of the SBD cell is laying on top of the AlGaN layer; or the first electrode of the sub cell corresponding to the Anode of the SBD cell is laying on top of a dielectric deposited on the AlGaN layer. Such implementation further described below with respect to FIGS. 7c (first alternative) and 7a (second alternative) allows flexibility in the layer composition and field management. The dielectric can be formed before the Ohmic metals or after formation of the Ohmic metals.

In an exemplary implementation of the semiconductor device, the first electrode (Anode) of the sub cell (SBD) extends into the AlGaN layer without reaching the GaN layer. Such implementation described below with respect to FIG. 7c allows flexible design of the Anode.

Note that in all designs presented below with respect to FIGS. 7a to 7e, the Cathode and/or Source terminals can be formed by etching away most of the barrier thickness, e.g. the AlGaN layer or part of it or even extend into the GaN layer 510.

In an exemplary implementation of the semiconductor device, the first electrode (Anode) of the sub cell (SBD) extends into the AlGaN layer up to the GaN layer without extending into the GaN layer. This implementation further described below with respect to FIG. 7d is an alternative to the above design and allows flexible design of the Anode.

In an exemplary implementation of the semiconductor device, the first electrode (Anode) of the sub cell (SBD) extends into the AlGaN layer and further extends into the GaN layer. This implementation further described below with respect to FIGS. 7a and 7c is an alternative to the above designs and allows further flexibility in the design of the Anode.

In an exemplary implementation of the semiconductor device, a Cathode metal of the SBD cell is arranged at the same or a different height above the top surface of the die layer than a Source metal of the HEMT cell. This configuration of field plates allows to specifically design the electric field at or above the top surface of the die layer.

In an exemplary implementation of the semiconductor device, the one or more unit cells are arranged in a staggered pattern across the top surface of the die layer without forming areas of the die layer in between the unit cells or at least subareas thereof which are not occupied by unit cells; or the one or more unit cells are aligned with respect to each other such that areas of the die layer in between the unit cells or at least subareas thereof are formed which are not occupied by unit cells.

In the first alternative, the area of the die layer is efficiently utilized without leaving unused spaces in between the unit cells. In the second alternative, the unit cells can be flexibly designed, for example, from a metallization and spacing point of view.

Even in the staggered pattern layout there can be areas of the die not occupied by the unit cell, specifically at the edges of the block.

Areas of the die layer in between the unit cells can cover the whole area between the unit cells of a unit block, or only a portion of this whole area, in this case, these areas are denoted as subareas. These subareas can be connected with each other and/or can be isolated from each other.

In an exemplary implementation of the semiconductor device, the semiconductor device comprises: one or more metal tracks arranged above the die layer for routing Source currents of the HEMT cells and Anode currents of the SBD cells. These metal tracks can run over the top surface of the die layer to collect the Source currents of the HEMT cells and the Anode currents of the SBD cells.

In an exemplary implementation of the semiconductor device, one or more SBD cells are shared between neighboring unit cells. This improves design flexibility and allows for a higher integration of SBD cells.

According to a second aspect, the disclosure relates to a method for manufacturing a semiconductor device, the method comprising: forming a die layer comprising a top surface and a bottom surface opposing the top surface such that the die layer forms a plurality of unit cells arranged side-by-side across the top surface of the die layer, wherein each unit cell comprises a sub cell of a first type and a sub cell of a second type which are both integrated in the unit cell; forming for each sub cell of the first type a first electrode, a second electrode and a third electrode at the top surface of the die layer, a first one of the three electrodes being arranged to enclose a second one of the three electrodes; and the first one and the second one of the three electrodes being arranged to enclose a third one of the three electrodes; wherein the sub cells of the first type form high electron mobility transistor, HEMT, cells; and wherein the sub cells of the second type form Schottky Barrier Diode, SBD, cells.

In such a method, the inserted SBD sub cells provide current conduction capability in reverse mode without the need of external Schottky diode. By such monolithically integration of intrinsic SBD sub cells in the unit cell of the GaN HEMT, additional parasitics can be reduced. Such integration of intrinsic SBD cells thus allows replacing the operation of body diodes in semiconductor technologies that do not contain a body diode, like GaN technology, for example. The absence of the body diode function that is used to assist the evacuation of reverse current can be retrieved by such integration of intrinsic SBD cells.

In an exemplary implementation of the method, the method comprises: forming for each sub cell of the second type a first electrode and a second electrode at the top surface of the die layer such that the second electrode of the sub cell of the second type is integrally formed with the third electrode of the sub cell of the first type. By such a manufacturing method, the unit cells can be space efficiently implemented. Multiple unit cells can be placed side-by-side without waste of die layer.

In an exemplary implementation of the method, the first electrode of a sub cell of the first type representing a gate electrode is formed before the first electrode of a sub cell of the second type representing an Anode electrode is formed; or the first electrode of a sub cell of the second type representing an Anode electrode is formed before the first electrode of a sub cell of the first type representing the gate electrode is formed.

The first alternative allows to implement the Gate first design for manufacturing the semiconductor device, e.g., the gate module is created first (until the gate metal), then the Anode and the Ohmic contact or metals are formed, as described below with respect to FIG. 7e. The second alternative allows to implement the Gate last design for manufacturing the semiconductor device, e.g., the Anode and the Ohmic contacts are created first and the gate module is created afterwards, as described below with respect to FIG. 7f.

In an exemplary implementation of the method, the method comprises: forming one or more field plates from a gate metal of the gate electrode by splitting the gate metal into one or more parts; and/or forming one or more field plates from an Ohmic metal of the second electrode of a sub cell of the first type representing a source electrode by splitting the Ohmic metal into one or more parts.

The first part is described below with respect to FIG. 7g and the second part is described below with respect to FIG. 7h. In the latter two implementations, the one or more parts of the split metal can be left electrically floating or can be set to another potential (ex. Connected to the source electrode to set its potential to the ground).

Forming field plates allows to specifically design the electric field at or above the top surface of the die layer.

### BRIEF DESCRIPTION OF THE DRAWINGS

Further embodiments of the disclosure will be described with respect to the following figures, in which:

FIG. 1 shows a schematic diagram of a semiconductor device 100 with a die layer 110 forming a plurality of unit cells 120 according to the disclosure and an exemplary unit cell 120 according to a first embodiment;

FIG. 2 shows a schematic top view of an exemplary unit cell 120 according to a second embodiment;

FIG. 3 shows a schematic top view of an exemplary unit cell 120 according to a third embodiment;

FIG. 4 shows a schematic top view of an exemplary unit cell 120 according to a fourth embodiment;

FIG. 5 shows a schematic top view of an exemplary unit cell 120 according to a fifth embodiment;

FIG. 6 shows a schematic top view of an exemplary unit cell 120 according to a sixth embodiment;

FIG. 7a shows a schematic cross section of a unit cell 120 according to a seventh embodiment;

FIG. 7b shows a schematic cross section of a unit cell 120 according to an eighth embodiment;

FIG. 7c shows a schematic cross section of a unit cell 120 according to a ninth embodiment;

FIG. 7d shows a schematic cross section of a unit cell 120 according to a tenth embodiment;

FIG. 7e shows a schematic cross section of a unit cell 120 according to an eleventh embodiment;

FIG. 7f shows a schematic cross section of a unit cell 120 according to a twelfth embodiment;

FIG. 7g shows a schematic cross section of a unit cell 120 according to a thirteenth embodiment;

FIG. 7h shows a schematic cross section of a unit cell 120 according to a fourteenth embodiment;

FIGS. 8a and 8b show schematic top views of a semiconductor device 100 in a staggered configuration (FIG. 8a) and in an aligned configuration (FIG. 8b) according to an embodiment;

FIGS. 8c and 8d show schematic top views of a semiconductor device 100 in a staggered configuration (FIG. 8c) and in an aligned configuration (FIG. 8d) according to an embodiment where the SBD area is shared between adjacent unit cells; and

FIG. 9 shows a schematic diagram illustrating a method 900 for manufacturing a semiconductor device according to the disclosure.

### DETAILED DESCRIPTION OF EMBODIMENTS

In the following detailed description, reference is made to the accompanying drawings, which form a part thereof, and in which is shown by way of illustration specific aspects in which the disclosure may be practiced. It is understood that other aspects may be utilized and structural or logical changes may be made without departing from the scope of the disclosure. The following detailed description, therefore, is not to be taken in a limiting sense, and the scope of the disclosure is defined by the appended claims.

It is understood that comments made in connection with a described method may also hold true for a corresponding device or system configured to perform the method and vice versa. For example, if a specific method step is described, a corresponding device may include a unit to perform the described method step, even if such unit is not explicitly described or illustrated in the figures. Further, it is understood that the features of the various exemplary aspects described herein may be combined with each other, unless specifically noted otherwise.

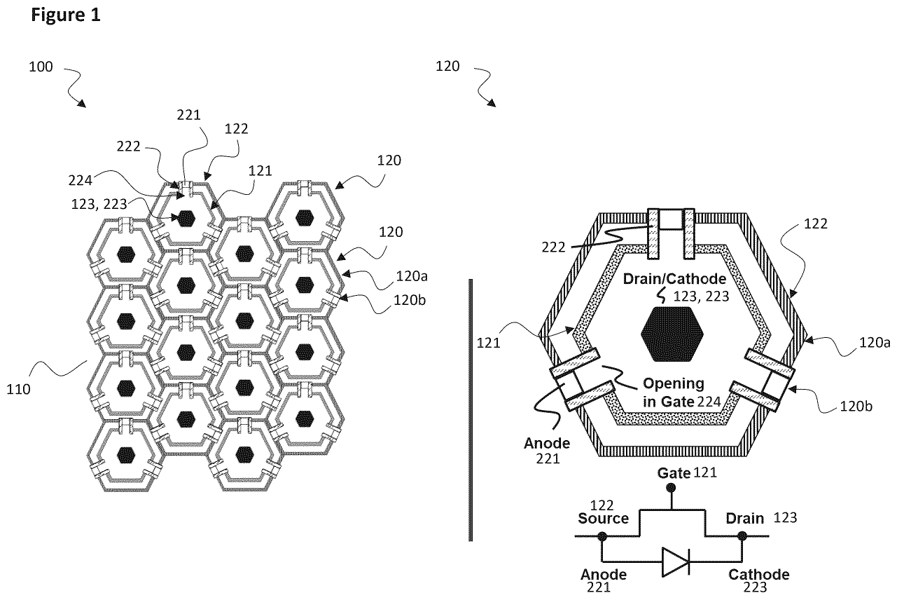

FIG. 1 shows a schematic diagram of a semiconductor device 100 with a die layer 110 forming a plurality of unit cells 120 according to the disclosure and an exemplary unit cell 120 according to a first embodiment.

The left picture in FIG. 1 is an exemplary implementation of such a semiconductor device. In this example, an exemplary unit block is illustrated which includes an exemplary number of 16 unit cells 120, each unit cell 120 comprising a sub cell of a first type 120a and a sub cell of a second type 120b which are both integrated in the unit cell 120. It understands that any other number of unit cells can be used as well.

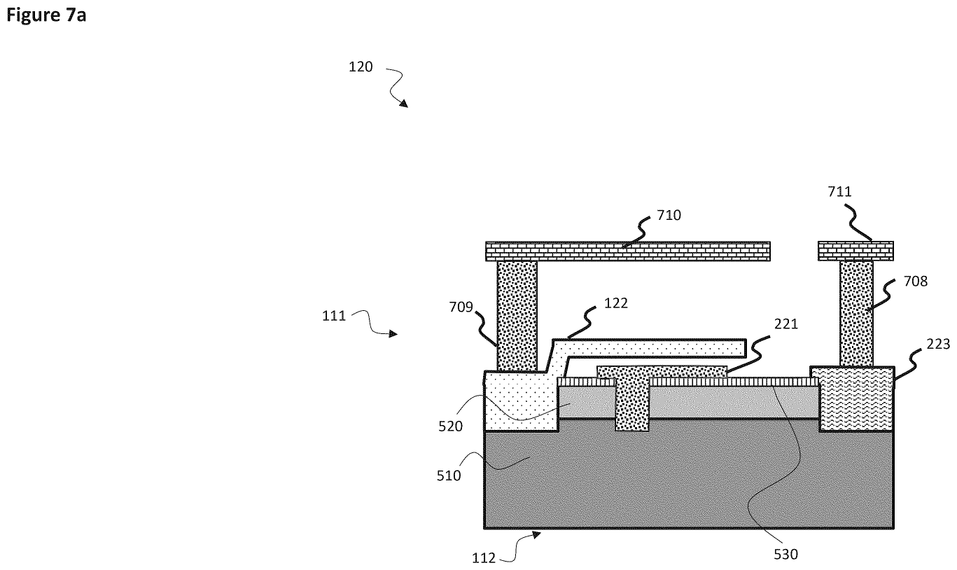

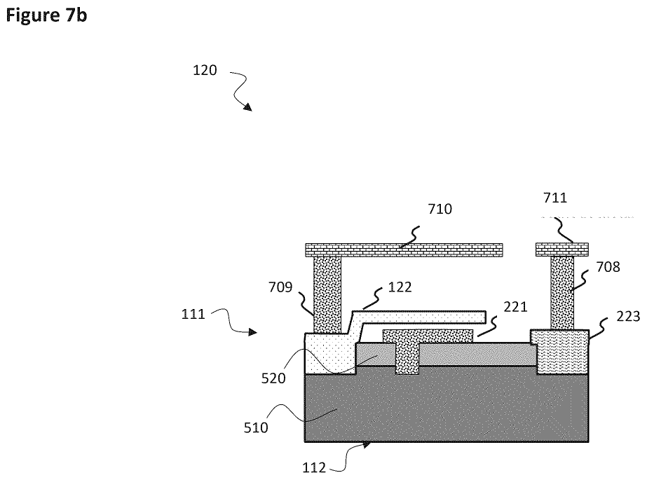

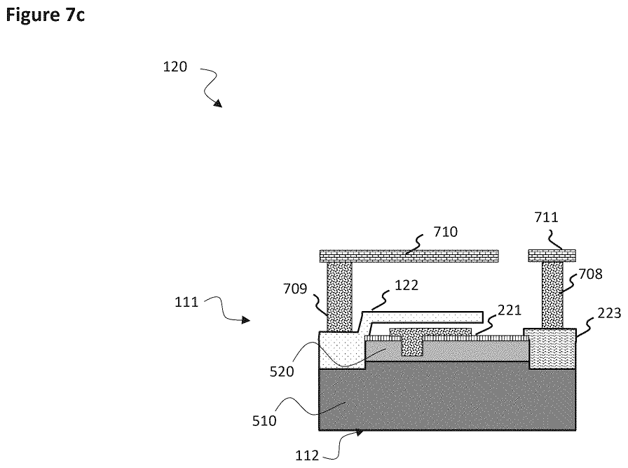

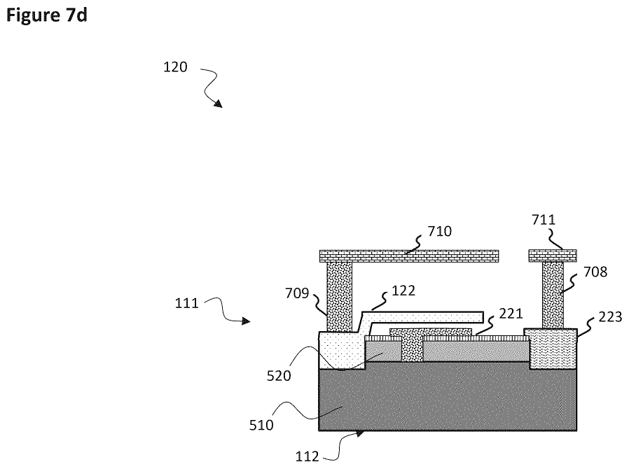

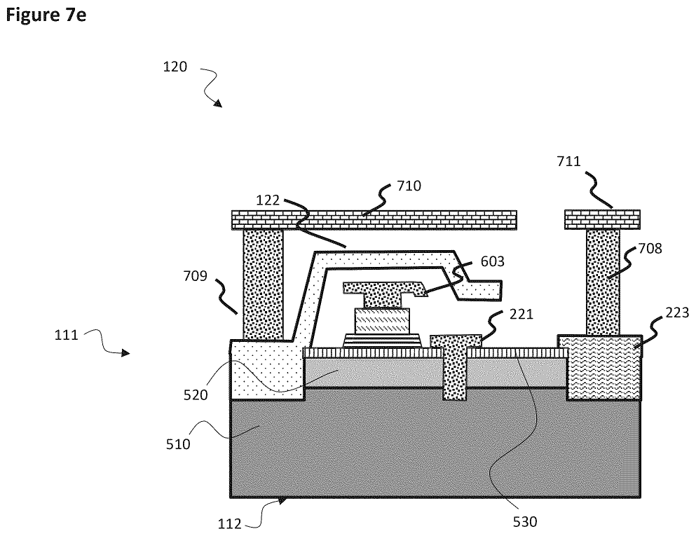

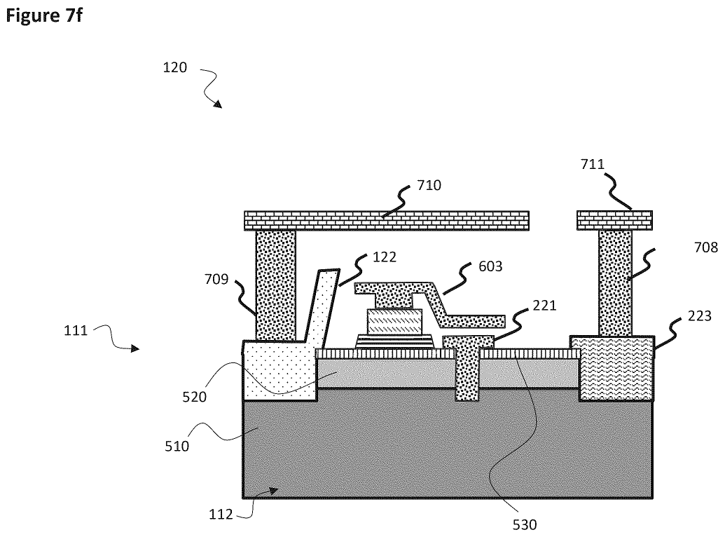

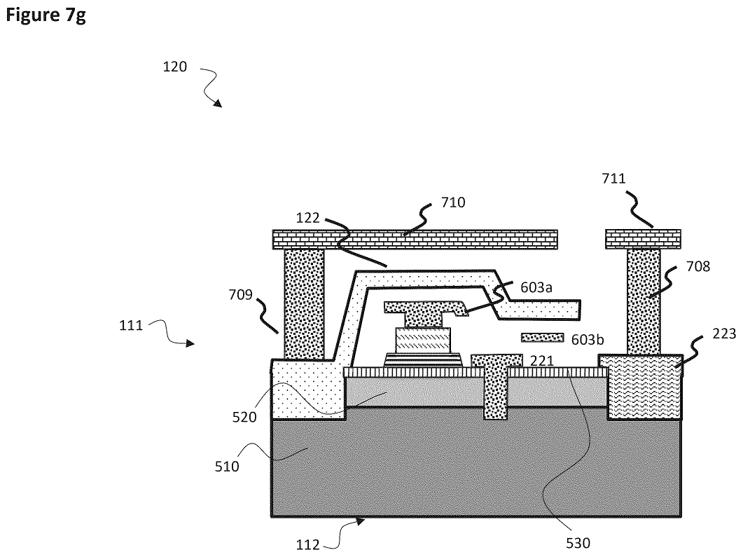

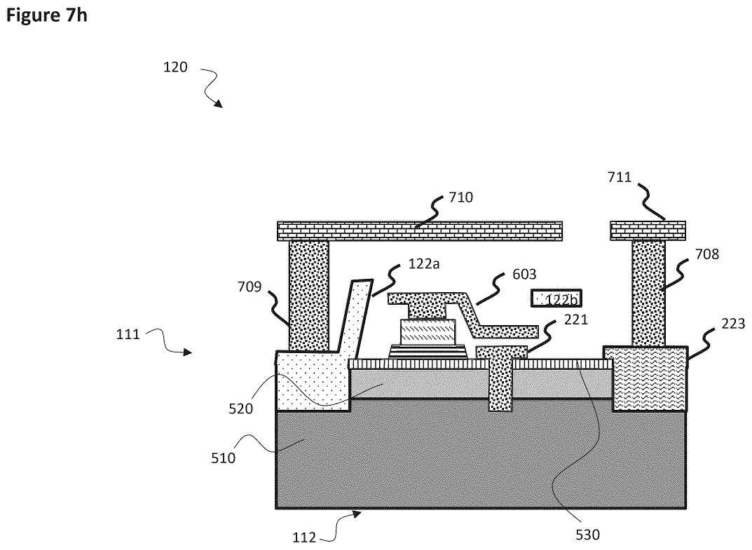

The semiconductor device 100 shown in FIG. 1 comprises: a die layer 110 comprising a top surface and a bottom surface opposing the top surface. FIG. 1 shows a top view on the top surface of the semiconductor device 100. Exemplary cross sections are shown in FIGS. 7a to 7i. The top surface of the die layer 110 is referred to as the top surface of the semiconductor device 100.

The die layer 110 forms a plurality of unit cells 120 arranged side-by-side across the top surface of the die layer 110. Each unit cell 120 comprises a sub cell of a first type 120a and a sub cell of a second type 120b which are both integrated in the unit cell 120.

The sub cell of the first type 120a comprises a first electrode 121, a second electrode 122 and a third electrode 123 formed at the top surface of the die layer 110.

A first one of the three electrodes 121, 122, 123 is arranged to enclose a second one of the three electrodes 121, 122, 123; and the first one and the second one of the three electrodes 121, 122, 123 are arranged to enclose a third one of the three electrodes 121, 122, 123.

The sub cells of the first type 120a form high electron mobility transistor, HEMT, cells. The sub cells of the second type 120b form Schottky Barrier Diode, SBD, cells.

Each sub cell of the second type 120b may comprise a first electrode 221, for example an Anode 221 as shown in FIG. 1, and a second electrode 223, for example a Cathode 223 as shown in FIG. 1, formed at the top surface of the die layer 110. The second electrode 223 of the sub cell of the second type 120b may be integrally formed with the third electrode 123, for example a Drain 123 as shown in FIG. 1, of the sub cell of the first type 120a.

For a respective unit cell 120, the HEMT cell 120a can be electrically connected to the SBD cell 120b as shown in the circuit diagram on the right bottom side of FIG. 1. e.g., Source 122 can be connected to Anode 221; and Drain 123 can be connected to Cathode 223. Gate 121 can be used for control.

The second electrode 223 of the sub cell of the second type 120b may form a Cathode 223 of the SBD cell 120b, the Cathode 223 of the SBD cell being integrally formed with a Drain 123 of the HEMT cell.

Each of the second electrode 122 and the first electrode 121 of a sub cell of the first type 120a may form a closed geometrical contour around the third electrode 123 of the sub cell of the first type 120a.

The closed geometrical contour of the first electrode 121 or of both the first electrode 121 and the second electrode 122 can be broken at one or more points 224 (see the openings 224 in gate in FIG. 1) at which the first electrode 221 of the sub cell of the second type 120b is formed.

The semiconductor device 100 may comprise an insulating layer 222 (or isolation layer, respectively) formed at the one or more points to electrically insulate the third electrode 223 of the sub cell of the first type 120a from the second electrode 122 of the sub cell of the first type 120a.

An Anode 221 of the SBD cell 120b may be arranged inside a Source 122 or inside a Gate 121 of the HEMT cell 120a. The Anode 221 can be insulated by the insulating layer 222.

As can be seen from FIG. 1, each of the second electrode 122 and the first electrode 121 of a sub cell of the first type 120a may form a closed geometrical contour around the third electrode 123 of the sub cell of the first type 120a.

The closed geometrical contour can be symmetrical about one or more directions along the top surface of the die layer 110. The closed geometrical contour can have at least one sharp corner, at least one rounded corner and/or at least one cut corner or any combination thereof.

At least one of the first electrode 121, the second electrode 122 and the third electrode 123 can be stretched in a direction along the top surface of the die layer 110. This stretched configuration is not shown in the Figures.

The closed geometrical contour can be a hexagon as shown in FIG. 1, an octagon, a triangle, a square, a rectangular or a circle.

In other words, FIG. 1 depicts an example of the hexagonal cell. It shows also a simplified equivalent electrical model which is a transistor with its main terminals (Source, Gate and Drain).

In this example, Drain 123 is inside, Source 122 outside and the Gate 121 between Source 122 and Drain 123 (with appropriate spacing to Drain 123 to sustain the targeted high voltage).

FIG. 1 (right side picture) represents a unit cell 120 according to a first embodiment: It contains an SBD derived from the GaN HEMT where the inner terminal is forming the Cathode 223, and the Schottky contacts (Anode 221) are inserted in the Source area. The locations where the Anodes are inserted are arbitrarily. A uniform distribution along the Source layer maximizes the protection. The area of each of these inserted Anodes is also arbitrarily. It can for example be set based on the level of the reverse current needed in any specific application.

The location and size of each inserted Anode can be independent from the others.

FIG. 1 (right side bottom picture) shows a simplified equivalent electrical model: a transistor with its main terminals (Source 122, Gate 121 and Drain 123) with a Schottky diode in parallel between Source 122 and Drain 123.

The Gate layer is interrupted in the vicinity of the areas where the Anodes are inserted. This is performed to open the path for the current conduction of the SBD. To prevent electrical shorts between the Drain and Source, an isolation layer is inserted between Gate and Source at each side of the Anode regions. In such way, the 2DEG used for the current conduction is interrupted forming a safe current path in front of the Anode regions.

The isolation layer can be (but not limited to) a dielectric layer, an implanted region with Oxygen or Nitrogen, etc.

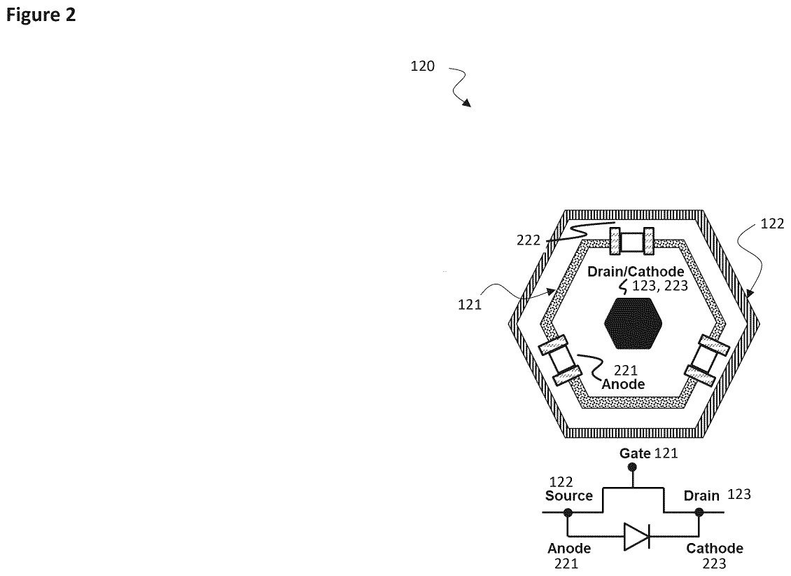

FIG. 2 shows a schematic top view of an exemplary unit cell 120 according to a second embodiment.

The unit cell 120 shown in FIG. 2 is another example of a unit cell 120 shown in the left side picture of FIG. 1.

In this second embodiment, the Anode regions are inserted in the Gate layer.

In this case, the current capability of the diode is enhanced due to shorter current path and less current crowding.

The Source layer can be left without interruption and the insulating layers 222 can be shorter (no need to overlap with the Source layer). In this specific case, the insulating layer might be omitted.

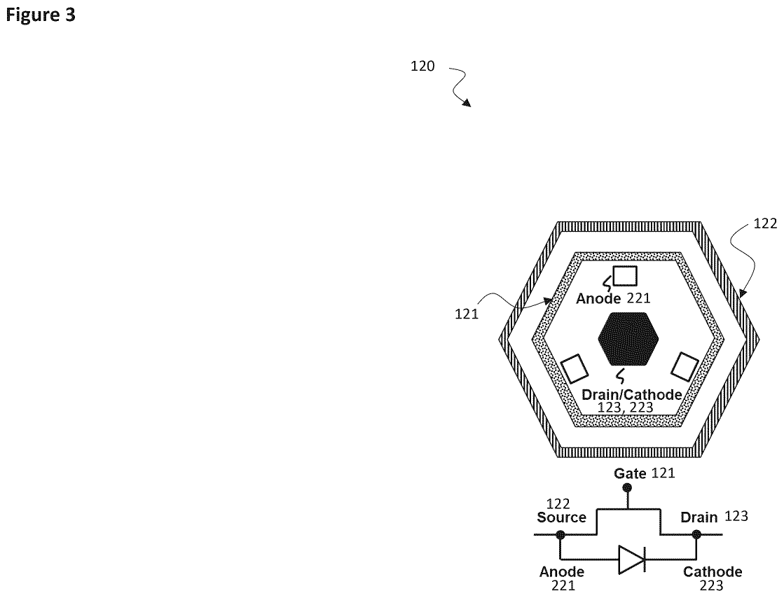

FIG. 3 shows a schematic top view of an exemplary unit cell 120 according to a third embodiment.

The unit cell 120 shown in FIG. 3 is another example of a unit cell 120 shown in the left side picture of FIG. 1.

In this example, an Anode 221 of the SBD cell can be arranged between a Drain 123 and a Gate 121 of the HEMT cell 120a as shown in FIG. 3.

In this third embodiment, the Anode regions are inserted between the Gate layer and the Drain layer.

In this example, the current capability of the diode is boosted (inversely proportional to the distance between the Anode layer and the Drain layer). This boost in current has to be compromised with the blocking voltage of the SBD and its leakage. These two items can be further optimized by the design of the FP configuration.

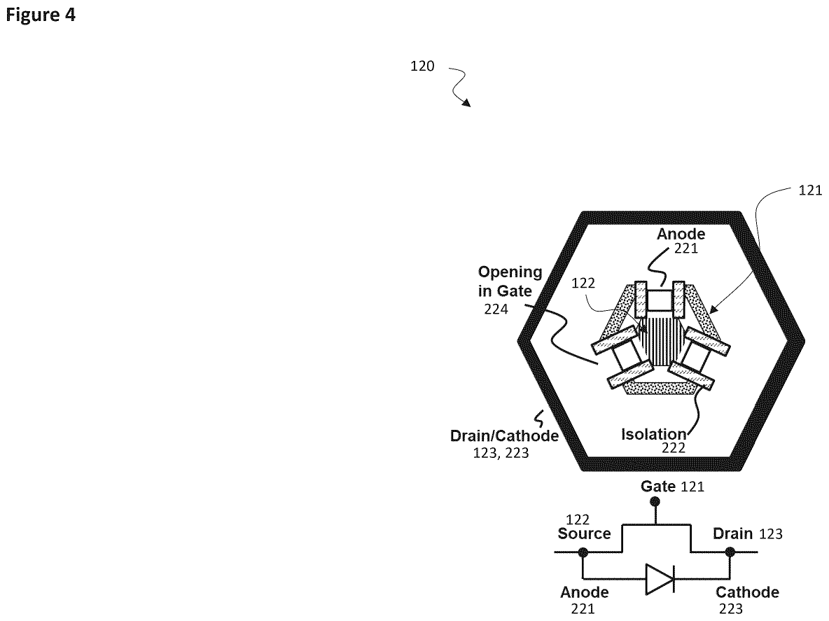

FIG. 4 shows a schematic top view of an exemplary unit cell 120 according to a fourth embodiment.

The unit cell 120 shown in FIG. 4 is another example of a unit cell 120 shown in the left side picture of FIG. 1.

This fourth embodiment contains an SBD derived from the GaN HEMT where the outer terminal is forming the Cathode, and the Schottky contacts (Anode) are inserted in the Source area.

The locations where the Anodes are inserted are arbitrarily. A uniform distribution along the Source layer maximizes the protection. The area of each of these inserted Anodes is also arbitrarily. It can for example be set based on the level of the reverse current needed in any specific application.

The location and size of each inserted Anode can be independent from the others.

FIG. 4 also shows a simplified equivalent electrical model: a transistor with its main terminals (Source, Gate and Drain) with a Schottky diode in parallel between Source and Drain.

The Gate layer is interrupted in the vicinity of the areas where the Anodes are inserted. This is performed to open the path for the current conduction of the SBD.

To prevent electrical shorts between the Drain and Source, an insulating layer 222 is inserted between Gate and Source at each side of the Anode regions. In such way, the 2DEG used for the current conduction is interrupted forming a safe current path in front of the Anode regions.

The insulating layer 222 can be for example (but not limited to) a dielectric layer, an implanted region with Oxygen or Nitrogen, etc.

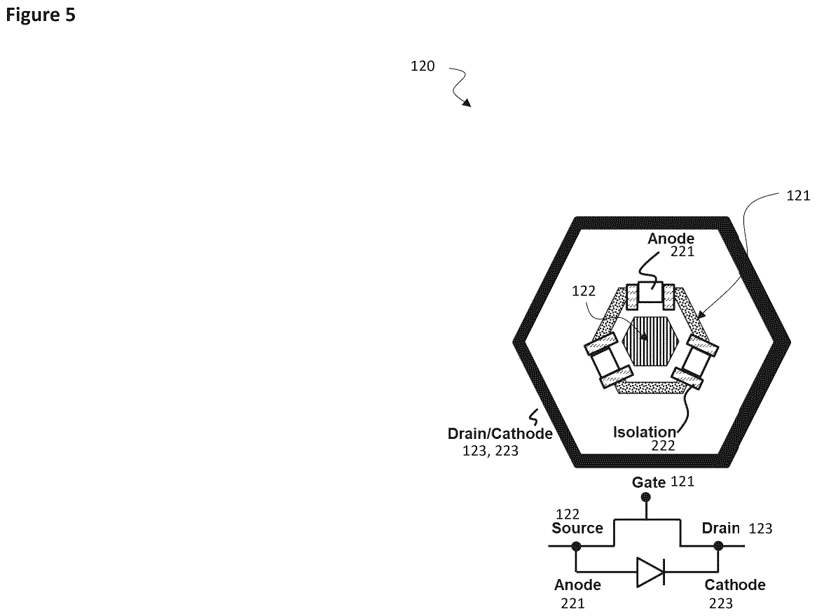

FIG. 5 shows a schematic top view of an exemplary unit cell 120 according to a fifth embodiment.

The unit cell 120 shown in FIG. 5 is another example of a unit cell 120 shown in the left side picture of FIG. 1.

This fifth embodiment represents an example where the Anode regions are inserted in the Gate layer.

In this case, the current capability of the diode is enhanced due to shorter current path and less current crowding.

The Source layer can be left without interruption and the isolation layers can be shorter (no need to overlap with the Source layer). In this specific case, the isolation layer can be omitted.

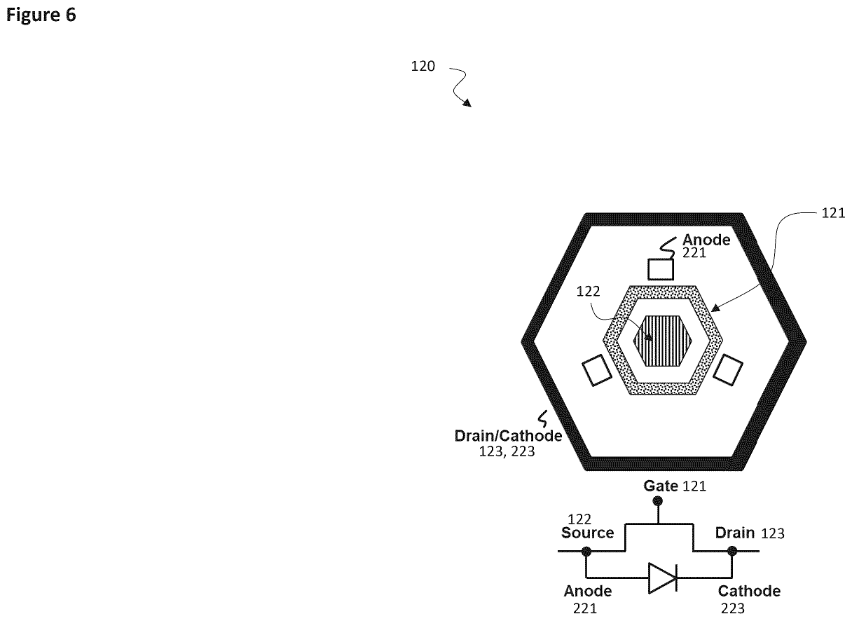

FIG. 6 shows a schematic top view of an exemplary unit cell 120 according to a sixth embodiment.

The unit cell 120 shown in FIG. 6 is another example of a unit cell 120 shown in the left side picture of FIG. 1.

This sixth embodiment represents an example where the Anode regions are inserted between the Gate layer and the Drain layer.

In this case, the current capability of the diode is boosted (inversely proportional to the distance between the Anode layer and the Drain layer). This boost in current is compromised with the blocking voltage of the SBD and its leakage. These two items can be further optimized by the design of the FP configuration.

In the previous embodiments, the hexagonal cell configurations were discussed. In the following sections, the implementation from a cross section point of view is discussed.

In the cross sections shown in FIGS. 7a to 7i, all white spaces above the AlGaN layer 520 may be covered by dielectrics unless otherwise noted. In some parts above the AlGaN layer 520 and below the Anode 221 there may be no dielectrics as described below.

FIG. 7a shows a schematic cross section of a unit cell 120 according to a seventh embodiment.

This seventh embodiment shows the use of any present metal layer as a field plate to shape the electric field at the surface between AlGaN and above layers (protection of Schottky edges and Cathode edges).

The dielectric(s) can be present on top of the AlGaN layer (below the Anode (221)) as shown in FIG. 7a or the dielectric(s) can be absent on top of the AlGaN layer (below the Anode (221)) as shown in FIG. 7b.

The unit cell 120 shown in FIG. 7a is an example of the unit cell 120 described above with respect to FIG. 1.

As can be seen from FIG. 7a, the die layer 110 shown in FIG. 1 comprises a Gallium Nitride (GaN) layer 510 and an Aluminum Gallium Nitride (AlGaN) layer 520 formed on top of the GaN layer 510. Any of the electrodes 221, 223 of the SBD cell 120b and the electrodes 121, 122, 123 of the HEMT cell 120a forms a field plate above the AlGaN layer 520. Extra field plates can be formed by splitting the electrodes 121, 123, 122, or by additional metals. For example, metals 710 and 711 can be used as field plates.

The first electrode 122 of the sub cell 120a corresponding to the Anode 221 of the SBD cell 120b is laying on top of a dielectric 530 deposited on the AlGaN layer 520 as can be seen from FIG. 7a.

Alternatively, the first electrode 122 of the sub cell 120a corresponding to the Anode 221 of the SBD cell 120b can be laying on top of the AlGaN layer 520 as shown in FIG. 7b, for example, where no dielectric 530 is used.

The first electrode 122 of the sub cell 120a extends into the AlGaN layer 520 and further extends into the GaN layer 510. It can also extend into the AlGaN layer 520 without extending into the GaN layer 510. The Anode 221 also extends into the AlGaN layer 520 and further into the GaN layer 510.

As can be seen from FIG. 7a, a via 709 is placed on top of the Ohmic metal forming the first electrode 122 which electrically connects the first electrode 122 with a source metal 710 above the top surface 111 of the die layer 110.

Another via 708 is placed on top of the Ohmic metal forming the second electrode 223 (Cathode) which electrically connects the second electrode 223 with a Cathode metal 711 above the top surface 111 of the die layer 110.

In this embodiment, the first electrode 221 of the SBD cell 120b extends into the AlGaN layer 520 and further extends into the GaN layer 510. The cathode and anode can be formed by etching all the barrier 520 thickness, and even extend to the GaN 510.

FIG. 7b shows a schematic cross section of a unit cell 120 according to an eighth embodiment.

The configuration is similar to FIG. 7a, e.g., a via 709 is placed on top of the Ohmic metal forming the first electrode 122 of the HEMT cell 120a which electrically connects the first electrode 122 with a source metal 710 above the top surface 111 of the die layer 110. Another via 708 is placed on top of the Ohmic metal forming the second electrode 223 (Cathode) of the SBD cell 120b which electrically connects the second electrode 223 with a Cathode metal 711 above the top surface 111 of the die layer 110.

In this embodiment, the first electrode 221 of the SBD cell 120b corresponding to the Anode is placed directly on top of the AlGaN layer 520 without a dielectrics 530 in between as shown in FIG. 7a.

In this embodiment, the first electrode 221 of the SBD cell 120b extends into the AlGaN layer 520 and further extends into the GaN layer 510.

FIG. 7c shows a schematic cross section of a unit cell 120 according to a ninth embodiment.

The configuration is similar to FIGS. 7a and 7b, e.g., a via 709 is placed on top of the Ohmic metal forming the first electrode 122 of the HEMT cell 120a which electrically connects the first electrode 122 with a source metal 710 above the top surface 111 of the die layer 110. Another via 708 is placed on top of the Ohmic metal forming the second electrode 223 (Cathode) of the SBD cell 120b which electrically connects the second electrode 223 with a Cathode metal 711 above the top surface 111 of the die layer 110.

In this configuration, the first electrode 221 of the SBD cell 120b extends into the AlGaN layer 520 without reaching the GaN layer 510.

In this embodiment, the Cathode 223 and/or the 122 terminals can be formed by etching away all of the barrier 520 thickness or part of it or even extend into the GaN layer 510.

The dielectric(s) can be present on top of the AlGaN layer 520 as shown in FIG. 7c or the dielectric(s) can be absent on top of the AlGaN layer.

FIG. 7d shows a schematic cross section of a unit cell 120 according to a tenth embodiment.

The main difference between FIG. 7d and the other FIGS. 7a, 7b, 7c described above is that the Anode 221 can be obtained by etching the total thickness of the barrier 520 without extending into the GaN layer 510.

The configuration is similar to FIGS. 7a to 7c, e.g., a via 709 is placed on top of the Ohmic metal forming the first electrode 122 of the HEMT cell 120a which electrically connects the first electrode 122 with a source metal 710 above the top surface 111 of the die layer 110. Another via 708 is placed on top of the Ohmic metal forming the second electrode 223 (Cathode) of the SBD cell 120b which electrically connects the second electrode 223 with a Cathode metal 711 above the top surface 111 of the die layer 110.

FIG. 7e shows a schematic cross section of a unit cell 120 according to an eleventh embodiment.

The configuration is similar to FIGS. 7a to 7d, e.g., a via 709 is placed on top of the Ohmic metal forming the first electrode 122 of the HEMT cell 120a which electrically connects the first electrode 122 with a source metal 710 above the top surface 111 of the die layer 110. Another via 708 is placed on top of the Ohmic metal forming the second electrode 223 (Cathode) of the SBD cell 120b which electrically connects the second electrode 223 with a Cathode metal 711 above the top surface 111 of the die layer 110.

As can be seen from FIG. 7e, the field plates of the first electrode 221 of the sub cell 120b corresponding to the Anode 221 of the SBD cell 120b and field plates of the second electrode 223 of the sub cell corresponding to the Cathode 223 of the SBD cell 120b and field plates of the gate electrode 603 and source electrode 122 of the SBD cell 120b may be arranged at different heights above the top surface of the die layer 110.

In this embodiment, the Cathode and/or the Anode terminals can be formed by etching away all of the barrier 520 thickness and extending through the layer 510 below the AlGaN barrier 520. In this configuration, the Anode 221 is extending through the AlGaN layer 520 down to the GaN layer 510 and extending into the GaN layer 510. Note that other configurations can be provided as well, where the Anode 221 is not reaching the GaN layer 510 or where the Anode 221 is stopping at the GaN layer 510.

The Anode 221 can be integrated next to the Gate terminal 603, e.g., between Gate 603 and Cathode 223. In this case, two configurations can be implemented depending on the technology: 1) Gate first design: In this configuration, the gate module is created first (until the gate metal 603), then the Anode 221 and the ohmic contact/metals are formed as shown in FIGS. 7e; and 2) Gate last design as described below with respect to FIG. 7f.

The dielectric(s) can be present on top of the AlGaN layer 520 as shown in FIG. 7a or the dielectric(s) can be absent on top of the AlGaN layer 520.

FIG. 7f shows a schematic cross section of a unit cell 120 according to a twelfth embodiment.

The configuration is similar to that described above with respect to FIG. 7c.

As described above, the Anode can be integrated next to the Gate terminal (between Gate and Cathode). In this case, the two configurations can be implemented depending on the technology: 1) Gate first design as described above with respect to FIGS. 7e; and 2) Gate last design as shown here in FIG. 7f: The Anode 221 and the Ohmic contacts/metals are created first. The Gate module 603 is created afterwards.

The dielectric(s) can be present on top of the AlGaN layer 520 as shown in FIG. 7f or the dielectric(s) can be absent on top of the AlGaN layer 520.

FIG. 7g shows a schematic cross section of a unit cell 120 according to a thirteenth embodiment. The configuration is similar to that described above with respect to FIGS. 7c and 7f.

The dielectric(s) can be present on top of the AlGaN layer 520 as shown in FIG. 7g or the dielectric(s) can be absent on top of the AlGaN layer 520.

Extra field plates 603a, 603b can be designed by splitting the Gate metal as shown in FIG. 7g.

FIG. 7h shows a schematic cross section of a unit cell 120 according to a fourteenth embodiment.

The dielectric(s) can be present on top of the AlGaN layer 520 as shown in FIG. 7h or the dielectric(s) can be absent on top of the AlGaN layer 520.

Extra field plates 122a, 122b can be designed by splitting the Ohmic metal of the first electrode 122 of the HEMT cell 120a as shown in FIG. 7h.

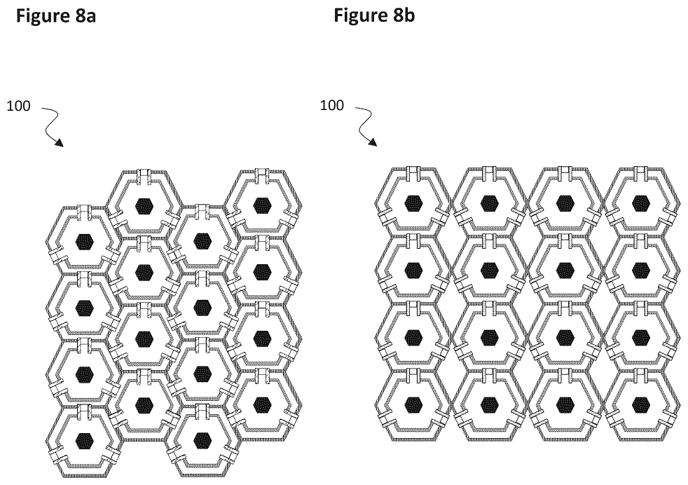

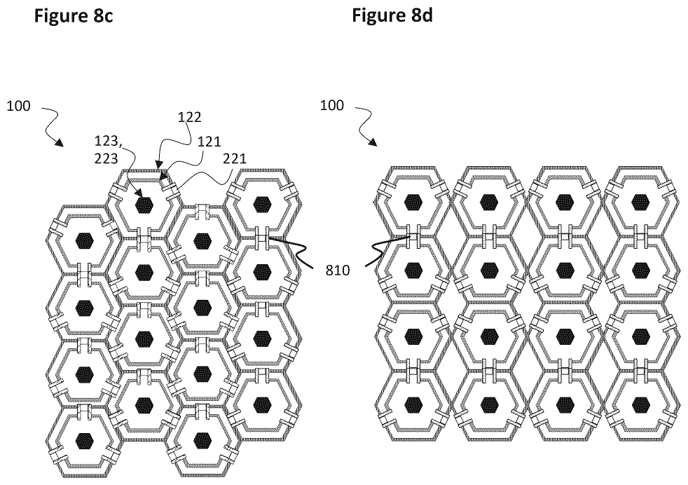

Any of the integrated intrinsic SBD described above (or any combination) can be used in a block of cells. The ratio of SBD area versus HEMT area in each unit cell can be set independently or in a uniform way. FIGS. 8a and 8b show examples of such a block in a staggered form (FIG. 8a) or aligned form (FIG. 8b).

FIGS. 8a and 8b show schematic top views of a semiconductor device 100 in a staggered configuration (FIG. 8a) and in an aligned configuration (FIG. 8b) according to an embodiment.

The full symmetry represented here is not mandatory. Other asymmetric configurations can be considered like shown in FIGS. 8c and 8d where a few hexagonal cells are modified to share the SBD area between adjacent unit cells.

The full metallization on top of the unit block is not shown here.

In the configuration shown in FIG. 8a, the one or more unit cells 120 are arranged in a staggered pattern across the top surface of the die layer 110 without forming areas of the die layer 110 in between the unit cells 120 or at least subareas thereof which are not occupied by unit cells 120.

In the configuration shown in FIG. 8b, the one or more unit cells 120 are aligned with respect to each other such that areas of the die layer 110 in between the unit cells 120 or at least subareas thereof are formed which are not occupied by unit cells 120.

Note that any embodiment described above can be inserted in a block of cells.

A mix of any of the previous embodiments can be inserted.

FIGS. 8c and 8d show schematic top views of a semiconductor device 100 in a staggered configuration (FIG. 8c) and in an aligned configuration (FIG. 8d) according to an embodiment where the SBD area is shared between adjacent unit cells.

In the staggered configuration shown in FIG. 8c, all SBD cells 120b are shared between neighboring unit cells 120.

In the aligned configuration shown in FIG. 8d, some SBD cells 810, e.g., a subset of all SBD cells, are shared between neighboring unit cells 120.

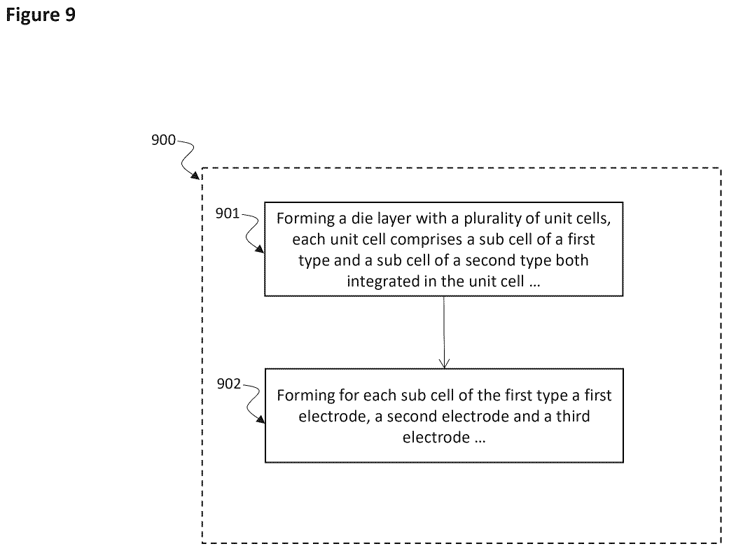

FIG. 9 shows a schematic diagram illustrating a method 900 for manufacturing a semiconductor device according to the disclosure.

The semiconductor device may correspond to one of the semiconductor devices 100 described above with respect to FIGS. 1 to 8d.

The method 900 comprises: forming 901 a die layer 110 comprising a top surface and a bottom surface opposing the top surface such that the die layer 110 forms a plurality of unit cells 120 arranged side-by-side across the top surface of the die layer 110, wherein each unit cell 120 comprises a sub cell of a first type 120a and a sub cell of a second type 120b which are both integrated in the unit cell 120.

The method 900 comprises: forming 902 for each sub cell 120a of the first type a first electrode 121, a second electrode 122 and a third electrode 123 at the top surface of the die layer 110, a first one of the three electrodes 121, 122, 123 being arranged to enclose a second one of the three electrodes 121, 122, 123; and the first one and the second one of the three electrodes 121, 122, 123 being arranged to enclose a third one of the three electrodes 121, 122, 123; wherein the sub cells of the first type 120a form high electron mobility transistor, HEMT, cells; and wherein the sub cells of the second type 120b form Schottky Barrier Diode, SBD, cells.

The method 900 may further comprise: forming for each sub cell of the second type 120b a first electrode 221 and a second electrode 223 at the top surface 111 of the die layer 110 such that the second electrode 223 of the sub cell of the second type 120b is integrally formed with the third electrode 123 of the sub cell of the first type 120a.

The first electrode 121, 603 of a sub cell 120a of the first type representing a gate electrode may be formed before the first electrode 221 of a sub cell 120b of the second type representing an Anode electrode 221 is formed.

Alternatively, the first electrode 221 of a sub cell 120b of the second type representing an Anode electrode 221 may be formed before the first electrode 121, 603 of a sub cell 120a of the first type representing the gate electrode is formed.

The method 900 may further comprise: forming one or more field plates 603a, 603b from a gate metal 603 of the gate electrode 121 by splitting the gate metal 603 into one or more parts; and/or forming one or more field plates 122a, 122b from an Ohmic metal 122 of the second electrode 122 of a sub cell 120a of the first type representing a source electrode by splitting the Ohmic metal 122 into one or more parts.

While a particular feature or aspect of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Also, the terms “exemplary”, “for example” and “e.g.” are merely meant as an example, rather than the best or optimal. The terms “coupled” and “connected”, along with derivatives may have been used. It should be understood that these terms may have been used to indicate that two elements cooperate or interact with each other regardless whether they are in direct physical or electrical contact, or they are not in direct contact with each other.

Although specific aspects have been illustrated and described herein, it will be appreciated by those of ordinary skill in the art that a variety of alternate and/or equivalent implementations may be substituted for the specific aspects shown and described without departing from the scope of the disclosure. This application is intended to cover any adaptations or variations of the specific aspects discussed herein.

Although the elements in the following claims are recited in a particular sequence with corresponding labeling, unless the claim recitations otherwise imply a particular sequence for implementing some or all of those elements, those elements are not necessarily intended to be limited to being implemented in that particular sequence.

Many alternatives, modifications, and variations will be apparent to those skilled in the art in light of the above teachings. Of course, those skilled in the art readily recognize that there are numerous applications of the disclosure beyond those described herein. While the disclosure has been described with reference to one or more particular embodiments, those skilled in the art recognize that many changes may be made thereto without departing from the scope of the disclosure. It is therefore to be understood that within the scope of the appended claims and their equivalents, the disclosure may be practiced otherwise than as specifically described herein.

What is claimed is:

1. A semiconductor device comprising:
a die layer comprising a top surface and a bottom surface opposing the top surface,
wherein the die layer forms a plurality of unit cells arranged side-by-side across the top surface of the die layer,
wherein each unit cell comprises a sub cell of a first type and a sub cell of a second type which are both integrated in the unit cell,
wherein the sub cell of the first type comprises three electrodes:
a first electrode, a second electrode and a third electrode formed at the top surface of the die layer, a first one of the three electrodes being arranged to enclose a second one of the three electrodes, and the first one and the second one of the three electrodes is arranged to enclose a third one of the three electrodes,
wherein the sub cells of the first type form high electron mobility transistor (HEMT) cells, and
wherein the sub cells of the second type form Schottky Barrier Diode (SBD) cells.

2. The semiconductor device of claim 1, wherein each sub cell of the second type comprises a first electrode and a second electrode formed at the top surface of the die layer, and
wherein the second electrode of the sub cell of the second type is integrally formed with the third electrode of the sub cell of the first type.

3. The semiconductor device of claim 2, wherein the second electrode of the sub cell of the second type forms a cathode of the SBD cell, and wherein the cathode of the SBD cell is integrally formed with a drain of the HEMT cell.

4. The semiconductor device of claim 1, wherein each of the second electrode and the first electrode of a sub cell of the first type forms a closed geometrical contour around the third electrode of the sub cell of the first type, and
wherein the closed geometrical contour of the first electrode or the second electrode or the closed geometrical contour of both the first electrode and the second electrode is broken at one or more points at which the first electrode of the sub cell of the second type is formed.

5. The semiconductor device of claim 4 further comprising:
an insulating layer formed at the one or more points to electrically insulate the first electrode of the sub cell of the second type from the first electrode or from both the first electrode and the second electrode of the sub cell of the first type.

6. The semiconductor device of claim 5, wherein an anode of the SBD cell is arranged inside a source or inside a gate of the HEMT cell, and wherein the anode is insulated by the insulating layer.

7. The semiconductor device of claim 1, wherein each of the second electrode and the first electrode of a sub cell of the first type forms a closed geometrical contour around the third electrode of the sub cell of the first type.

8. The semiconductor device of claim 7, wherein an anode of the SBD cell is arranged between a drain and a gate of the HEMT cell.

9. The semiconductor device of claim 7, wherein the closed geometrical contour is symmetrical about one or more directions along the top surface of the die layer, and
wherein the closed geometrical contour has at least one sharp corner, at least one rounded corner and/or at least one cut corner or any combination thereof.

10. The semiconductor device of claim 1, wherein at least one of the first electrode, the second electrode and the third electrode is stretched in a direction along the top surface of the die layer.

11. The semiconductor device of claim 5, wherein the closed geometrical contour is a hexagon, an octagon, a triangle, a square, a rectangular or a circle.

12. The semiconductor device of claim 1, wherein the die layer comprises a gallium nitride (GaN) layer and an aluminum gallium nitride (AlGaN) layer formed on top of the GaN layer, and
wherein any of the electrodes of the SBD cell and the electrodes of the HEMT cell forms a field plate above the AlGaN layer.

13. The semiconductor device of claim 12, wherein the first electrode of the sub cell corresponding to the anode of the SBD cell is laying on top of the AlGaN layer, or
wherein the first electrode of the sub cell corresponding to the Anode of the SBD cell is laying on top of a dielectric deposited on the AlGaN layer.

14. The semiconductor device of claim 12, wherein the first electrode of the sub cell extends into the AlGaN layer without reaching the GaN layer.

15. The semiconductor device of claim 12, wherein the first electrode of the sub cell extends into the AlGaN layer up to the GaN layer without extending into the GaN layer.

16. The semiconductor device of claim 12, wherein the first electrode of the sub cell extends into the AlGaN layer and further extends into the GaN layer.

17. The semiconductor device of claim 1, wherein a cathode metal of the SBD cell is arranged at the same or a different height above the top surface of the die layer than a source metal of the HEMT cell.

18. The semiconductor device of claim 1, wherein the one or more unit cells are arranged in a staggered pattern across the top surface of the die layer without forming areas of the die layer in between the unit cells or at least subareas thereof which are not occupied by unit cells, or
wherein the one or more unit cells are aligned with respect to each other such that areas of the die layer in between the unit cells or at least subareas thereof are formed which are not occupied by unit cells.

19. The semiconductor device of claim 1, further comprising one or more metal tracks arranged above the die layer for routing source currents of the HEMT cells and anode currents of the SBD cells.

20. The semiconductor device of claim 1, wherein one or more SBD cells are shared between neighboring unit cells.

21. A method for manufacturing a semiconductor device, the method comprising:
forming a die layer comprising a top surface and a bottom surface opposing the top surface such that the die layer forms a plurality of unit cells arranged side-by-side across the top surface of the die layer, wherein each unit cell comprises a sub cell of a first type and a sub cell of a second type which are both integrated in the unit cell; and
forming, for each sub cell of the first type, three electrodes: a first electrode, a second electrode and a third electrode at the top surface of the die layer, a first one of the three electrodes being arranged to enclose a second one of the three electrodes; and the first one and the second one of the three electrodes being arranged to enclose a third one of the three electrodes,
wherein the sub cells of the first type form high electron mobility transistor (HEMT) cells, and
wherein the sub cells of the second type form Schottky barrier diode (SBD) cells.

22. The method of claim 21, comprising forming for each sub cell of the second type a first electrode and a second electrode at the top surface of the die layer such that the second electrode of the sub cell of the second type is integrally formed with the third electrode of the sub cell of the first type.

23. The method of claim 22, wherein the first electrode of a sub cell of the first type representing a gate electrode is formed before the first electrode of a sub cell of the second type representing an anode electrode is formed, or
wherein the first electrode of a sub cell of the second type representing an Anode electrode is formed before the first electrode of a sub cell of the first type representing the gate electrode is formed.

24. The method of claim 22, further comprising:
forming one or more field plates from a gate metal of the gate electrode by splitting the gate metal into one or more parts; and/or
forming one or more field plates from an Ohmic metal of the second electrode of a sub cell of the first type representing a source electrode by splitting the Ohmic metal into one or more parts.
